(19) United States
(12) Patent Application Publication
(10) Pub. No.: US 2014/0218337 A1
(43) Pub. Date: Aug. 7, 2014

(54) ELECTRONIC DEVICE, INPUT PROCESSING METHOD AND PROGRAM

(71) Applicant: Panasonic Corporation, Osaka (JP)

(72) Inventors: Takeshi Yamaguchi, Kanagawa (JP); Tomoki Takano, Kanagawa (JP)

(73) Assignee: Panasonic Corporation, Osaka (JP)

(21) Appl. No.: 14/169,874

(22) Filed: Jan. 31, 2014

(30) Foreign Application Priority Data
Feb. 1, 2013 (JP) 2013-018392
Apr. 26, 2013 (JP) 2013-093660

(51) Int. Cl. G06F 3/044; H01L 27/32; G02F 1/1333

(52) U.S. Cl. CPC G06F 3/044; G02F 1/13338; H01L 27/323
USPC 345/174

(57) ABSTRACT

A touch panel layer has an electrostatic capacitance which changes according to a distance from an external object and outputs a signal of intensity which differs according to the change in the electrostatic capacitance. A coordinate acquiring section determines a contact state in which an external object touches the touch panel layer or a proximity state in which the external object is located within a predetermined distance from the touch panel layer, based on the intensity of the signal. A state determination section determines the contact state or the proximity state based on the result of state determination made by the coordinate acquiring section and the result of detection performed by a depression acquiring section. A touch coordinate processing section performs processing associated with a touch input operation. A hover coordinate processing section performs processing associated with a hover operation.

### CROSS REFERENCE TO RELATED APPLICATIONS

This application is entitled and claims the benefit of Japanese Patent Application No. 2013-018392, filed on Feb. 1, 2013, and Japanese Patent Application No. 2013-093660, filed on Apr. 26, 2013, the disclosures of which including the specifications, drawings and abstracts are incorporated herein by reference in their entirety.

### TECHNICAL FIELD

The present invention relates to an electronic device provided with a touch panel, an input processing method, and a program.

### BACKGROUND ART

In recent years, communication terminal apparatuses provided with a touch panel are becoming widespread. Such communication terminal apparatuses are provided with an input apparatus used for inputting data by operating a touch panel with human finger(s) or the like.

Conventionally, there have been a variety of input schemes for a touch panel. Among them, an input apparatus of an electrostatic capacitance coupling type, which is a main scheme, makes it possible to perform an operation of causing an object to be physically in contact (to touch) with the touch panel for input (hereinafter, described as “touch input operation”) and an operation of locating an object in proximity to the touch panel for displaying a menu or the like (hereinafter, described as “hover operation”). Whether an object is touching the touch panel or is located in proximity to the touch panel can be judged based on a change in electrostatic capacitance in the touch panel.

Meanwhile, the touch input operation is impossible with an input apparatus of an electrostatic capacitance coupling type when a user makes contact with the touch panel through a glove. This is because since a glove is non-conductive, a change in electrostatic capacitance is so small that it is generally impossible to judge that the touch panel is touched. In reality, the user may operate the touch panel with a glove on his or her hand, however, so that it is preferable to allow the user to perform the touch input operation even when the user makes contact with the touch panel through a glove.

Conventionally, an input apparatus has been known which switches between an operation mode that allows for touch input operation with a bare hand and an operation mode that allows for touch input operation through a glove, when the screen of the touch panel is unlocked. Accordingly, this input apparatus allows the user to perform touch input operation through the glove. However, with this input apparatus, it is necessary to lock the screen every time switching is made between the above-described operation modes, resulting in a problem of not being user-friendly.

To solve the above-described problem, a conventional input apparatus has been known which automatically switches between the operation mode that allows for touch input operation with a bare hand and the operation mode that allows touch input operation through a glove (e.g., see Japanese Patent Application Laid-Open No. 2009-181232 (hereinafter, referred to as “PTL 1”)). The input apparatus disclosed in PTL 1 is provided with two high and low sensor output thresholds including a first sensor output threshold and a second sensor output threshold, and the input apparatus judges that a touch input operation with a bare hand is performed when the sensor output is less than the first sensor output threshold and judges that a touch input operation through a glove is performed when the sensor output is equal to or greater than the first sensor output threshold but less than the second sensor output threshold.

### CITATION LIST

### Patent Literature

PTL 1

Japanese Patent Application Laid-Open No. 2009-181232

### SUMMARY OF INVENTION

### Technical Problem

However, when the input apparatus according to PTL 1 is applied to an input apparatus which allows for the touch input operation and hover operation, there is no significant difference in an electrostatic capacitance change between when the touch input operation is performed through a glove and when the hover operation is performed with a bare hand. Therefore, it is difficult to make a distinction between the operations. Moreover, with the input apparatus according to PTL 1, there is no significant difference in an electrostatic capacitance change between when the touch input operation is performed through a glove and when the hover operation is performed through a glove, and it is difficult to make a distinction between the operations. Therefore, the input apparatus according to PTL 1 may judge that the user has performed an operation which is not actually intended by the user.

An object of the present invention is to provide an electronic device, an input processing method, and a program capable of distinguishing all of various operations by a conductive external object such as fingers and various operations by a non-conductive external object such as a glove, thereby enabling user-intended operations to be reliably performed.

### Solution to Problem

An electronic device according to an aspect of the present invention includes: a planar display section; a planar transparent member that has a predetermined transmittance and that is disposed while being overlapped with the display section; a touch panel layer that is disposed between the display section and the transparent member while being overlapped with the display section and that detects two-dimensional coordinates of an indicator having predetermined conductivity along a surface of the display section and that detects a vertical distance from the indicator to the touch panel layer; and a depression detecting section that detects deformation of at least the transparent member, in which: when the vertical distance detected by the touch panel layer is equal to or less than a first value, the electronic device performs processing associated with touch input for at least the two-dimensional coordinates detected by the touch panel layer; and when the vertical distance is greater than the first value but not greater than a second value that is a value greater than the first value, and also when the depression detecting section detects predetermined deformation, the electronic device performs processing associated with touch input for at least the two-dimensional coordinates.

An input processing method is a method useable for an electronic device that includes: a planar display section; a planar transparent member that has a predetermined transmittance and that is disposed while being overlapped with the display section; a touch panel layer that is disposed between the display section and the transparent member while being overlapped with the display section and that detects two-dimensional coordinates of an indicator having predetermined conductivity along a surface of the display section and that detects a vertical distance from the indicator to the touch panel layer; and a depression detecting section that detects deformation of at least the transparent member, the input processing method including: performing processing associated with touch input for at least the two-dimensional coordinates detected by the touch panel layer, when the vertical distance detected by the touch panel layer is equal to or less than a first value; and performing processing associated with touch input for at least the two-dimensional coordinates, when the vertical distance is greater than the first value but not greater than a second value that is a value greater than the first value, and also when the depression detecting section detects predetermined deformation.

An input processing program according to an aspect of the present invention is a program for causing a computer to execute the processing for an electronic device that includes: a planar display section; a planar transparent member that has a predetermined transmittance and that is disposed while being overlapped with the display section; a touch panel layer that is disposed between the display section and the transparent member while being overlapped with the display section and that detects two-dimensional coordinates of an indicator having predetermined conductivity along a surface of the display section and that detects a vertical distance from the indicator to the touch panel layer; and a depression detecting section that detects deformation of at least the transparent member, the input processing program causing the computer to execute the processing including: performing processing associated with touch input for at least the two-dimensional coordinates detected by the touch panel layer, when the vertical distance detected by the touch panel layer is equal to or less than a first value; and performing processing associated with touch input for at least the two-dimensional coordinates, when the vertical distance is greater than the first value but not greater than a second value that is a value greater than the first value, and also when the depression detecting section detects predetermined deformation.

### Advantageous Effects of Invention

According to the present invention, it is possible to distinguish all of various operations by a conductive external object such as fingers and various operations by a non-conductive external object such as a glove, thereby enabling user-intended operations to be reliably performed.

### BRIEF DESCRIPTION OF DRAWINGS

FIG. 1 is a block diagram illustrating a configuration of an input apparatus according to Embodiment 1 of the present invention;

FIG. 2 is a flowchart illustrating operation of the input apparatus according to Embodiment 1 of the present invention;

FIG. 3 is a diagram illustrating a positional relationship between an external object and a touch panel layer according to Embodiment 1 of the present invention;

FIG. 4 is a block diagram illustrating a configuration of an input apparatus according to Embodiment 2 of the present invention;

FIG. 5 is a flowchart illustrating operation of the input apparatus according to Embodiment 2 of the present invention;

FIG. 6 is a diagram illustrating a positional relationship between an external object and a touch panel layer according to Embodiment 2 of the present invention;

FIG. 7 is a block diagram illustrating a configuration of an input apparatus according to Embodiment 3 of the present invention;

FIG. 8 is a flowchart illustrating operation of the input apparatus according to Embodiment 3 of the present invention;

FIG. 9 is a diagram illustrating a positional relationship between an external object and a touch panel layer according to Embodiment 3 of the present invention;

FIG. 10 is a block diagram illustrating a schematic configuration of an electronic device according to Embodiment 4 of the present invention;

FIG. 11 is a perspective view illustrating an appearance of the electronic device in FIG. 10;

FIG. 12 illustrates an arrangement of glass, a depression sensor and a display section of the electronic device in FIG. 10;

FIG. 13 illustrates a positional relationship between a touch panel layer of the electronic device in FIG. 10 and a finger;

FIG. 14 illustrates how a control section makes determinations with respect to detection states of the touch panel layer and the depression sensor of the electronic device in FIG. 10;

FIGS. 15A and 15B illustrate an example of how an icon is displayed in the electronic device in FIG. 10;

FIG. 16 illustrates finger detection states in the electronic device in FIG. 10 when the finger is gradually brought into proximity with the touch panel layer, contact with the touch panel layer and then is gradually separated from the touch panel layer;

FIG. 17 illustrates glove detection states in the electronic device in FIG. 10 when a gloved finger is gradually brought into proximity with the touch panel layer, contact with the touch panel layer and is then gradually separated from the touch panel layer;

FIG. 18 illustrates nail detection states in the electronic device in FIG. 10 when a nail is gradually brought into proximity with the touch panel layer, contact with the touch panel layer and is then gradually separated from the touch panel layer;

FIG. 19 is a flowchart illustrating indicator determination processing by the electronic device in FIG. 10;

FIG. 20 is a perspective view illustrating an example of the electronic device in FIG. 10 when a band-shaped depression sensor is placed along one of both short sides of the display section;

FIG. 21 is a perspective view illustrating an example of the electronic device in FIG. 10 when four band-shaped depression sensors are used while being arranged along four sides of the display section, respectively;

FIG. 22 illustrates an arrangement of glass, a touch panel layer, a depression sensor and a display section in application example 1 of the electronic device in FIG. 10;

FIG. 23 illustrates an arrangement of glass, a touch panel layer, a depression sensor and a display section in application example 2 of the electronic device in FIG. 10;

FIG. 24 illustrates an arrangement of glass, a touch panel layer, a depression sensor and a display section in application example 3 of the electronic device in FIG. 10;

FIG. 25 illustrates an arrangement of glass, a touch panel layer, a depression sensor and a display section in application example 4 of the electronic device in FIG. 10;

FIG. 26 illustrates an arrangement of glass, a touch panel layer, a depression sensor and a display section in application example 5 of the electronic device in FIG. 10;

FIG. 27 illustrates an arrangement of glass, a touch panel layer, a depression sensor and a display section in application example 6 of the electronic device in FIG. 10;

FIG. 28 illustrates an arrangement of glass, a touch panel layer, a depression sensor and a display section in an application example 7 of the electronic device in FIG. 10;

FIG. 29 illustrates an arrangement of glass, a touch panel layer, a depression sensor and a display section in application example 8 of the electronic device in FIG. 10;

FIG. 30 illustrates a schematic configuration of an electrostatic-capacitance touch panel; and

FIGS. 31A, 31B and 31C illustrate finger detection states when a hand is gradually brought into proximity with a touch panel.

### DESCRIPTION OF EMBODIMENTS

Hereinafter, embodiments of the present invention will be described in detail with reference to the accompanying drawings.

### Embodiment 1

<Configuration of Input Apparatus>

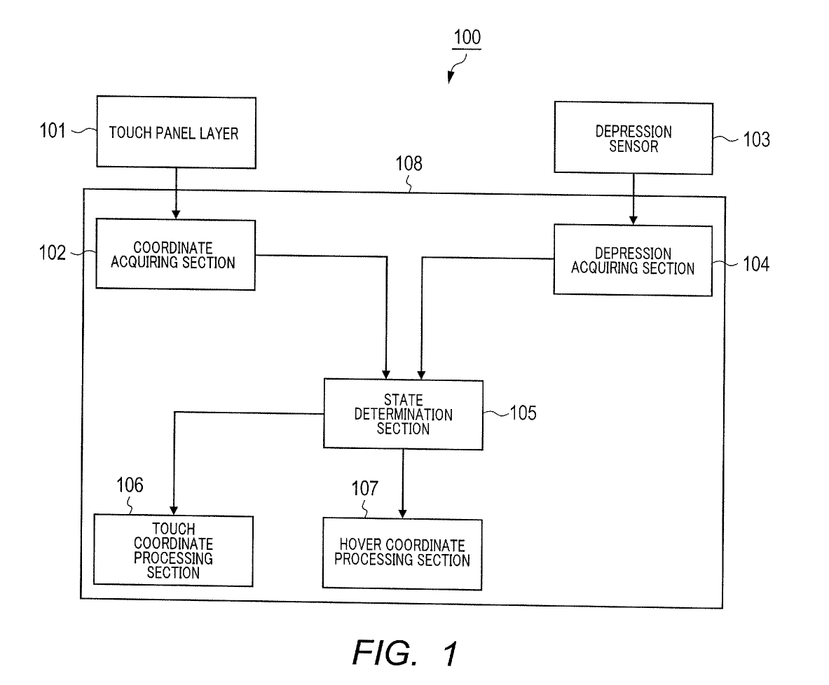

A configuration of input apparatus 100 according to Embodiment 1 of the present invention will be described with reference to FIG. 1.

Input apparatus 100 mainly includes touch panel layer 101, coordinate acquiring section 102, depression sensor 103, depression acquiring section 104, state determination section 105, touch coordinate processing section 106, and hover coordinate processing section 107.

Touch panel layer 101 is an electrostatic-capacitance-coupling-type touch panel layer having a display function. Touch panel layer 101 has a plurality of electrodes (not shown) arranged in parallel to two mutually orthogonal directions (X direction and Y direction). Touch panel layer 101 forms capacitors at intersections of the mutually orthogonal electrodes. The electrostatic capacitance of each of the above-described capacitors changes in accordance with a position of an external object and a distance from the external object, and touch panel layer 101 outputs a signal intensity that varies depending on the change in the electrostatic capacitance from each electrode to coordinate acquiring section 102. The external object in this embodiment refers to a human hand or a gloved human hand, for example.

Coordinate acquiring section 102 detects coordinates touched by the external object or coordinates approached by the external object based on the intensity of a signal outputted from each electrode of touch panel layer 101.

Coordinate acquiring section 102 determines a state of the external object based on the intensity of the signal outputted from each electrode of touch panel layer 101. More specifically, coordinate acquiring section 102 determines a contact state in which the external object touches touch panel layer 101 and a proximity state in which the external object is located in a proximity space within a predetermined distance from touch panel layer 101.

For example, when the intensity of the signal is equal to or above threshold S1 but less than threshold S2 (threshold S1<threshold S2), coordinate acquiring section 102 determines this state to be a proximity state. When the intensity of the signal is equal to or above threshold S2, coordinate acquiring section 102 determines this state to be a contact state. Furthermore, when the intensity of the signal is less than threshold S1, coordinate acquiring section 102 determines the state to be neither contact state nor proximity state.

Coordinate acquiring section 102 outputs the result of coordinate detection and the result of external object state determination (hereinafter described as “state determination result”) to state determination section 105.

Note that in the present embodiment, although coordinate acquiring section 102 determines a contact state and a proximity state based on a change in an electrostatic capacitance, the proximity state may also be determined by detection of reflected infrared light, detection of reflected ultrasound or image analysis using a camera (including 3D image analysis using a plurality of cameras).

Depression sensor 103 is stacked on touch panel layer 101. Depression sensor 103 outputs a voltage value which varies depending on a depression force from outside to depression acquiring section 104. Depression sensor 103 is, for example, a piezoelectric element. Note that depression sensor 103 is not necessarily stacked on touch panel layer 101 as long as depression sensor 103 can detect that a load is applied to touch panel layer 101. For example, depression sensor 103 may be placed on a whole or part of a back surface of touch panel layer 101 (more specifically, one of four sides or four corners) or on a housing to which touch panel layer 101 is fixed.

Depression acquiring section 104 detects a depression on touch panel layer 101 based on a voltage value inputted from depression sensor 103. For example, depression acquiring section 104 detects a depression when a voltage value or an accumulated value of voltage values inputted from depression sensor 103 is equal to or above a threshold, depression acquiring section 104 outputs the presence or absence of a depression to state determination section 105 as a detection result.

State determination section 105 determines the state to be a contact state if a detection result showing the presence of a depression is inputted from depression acquiring section 104 even when the state determination result inputted from coordinate acquiring section 102 shows a proximity state. When the state determination result inputted from coordinate acquiring section 102 shows a proximity state and a detection result showing the absence of a depression is inputted from depression acquiring section 104, state determination section 105 determines the state to be a proximity state. Furthermore, when the state determination result inputted from coordinate acquiring section 102 shows a contact state, state determination section 105 determines the state to be a contact state.

Upon determining that the state is a contact state, state determination section 105 notifies touch coordinate processing section 106 of the coordinates inputted from coordinate acquiring section 102. Upon determining that the state is a proximity state, state determination section 105 notifies hover coordinate processing section 107 of the coordinates inputted from coordinate acquiring section 102. Note that the method of determining a state of an external object employed by state determination section 105 will be described later.

Touch coordinate processing section 106 performs processing associated with a touch input operation at the coordinates notified from state determination section 105. For example, when a keyboard is displayed on touch panel layer 101, and a touch input operation is performed using a key of the keyboard displayed, touch coordinate processing section 106 displays the number corresponding to the key used in the touch input operation on touch panel layer 101.

Hover coordinate processing section 107 performs processing associated with hover operation at the coordinates notified from state determination section 105. For example, when a map is displayed on touch panel layer 101 and hover operation is performed on the icon on the map displayed, hover coordinate processing section 107 displays information associated with the hover-operated icon on touch panel layer 101.

<Operation of Input Apparatus>

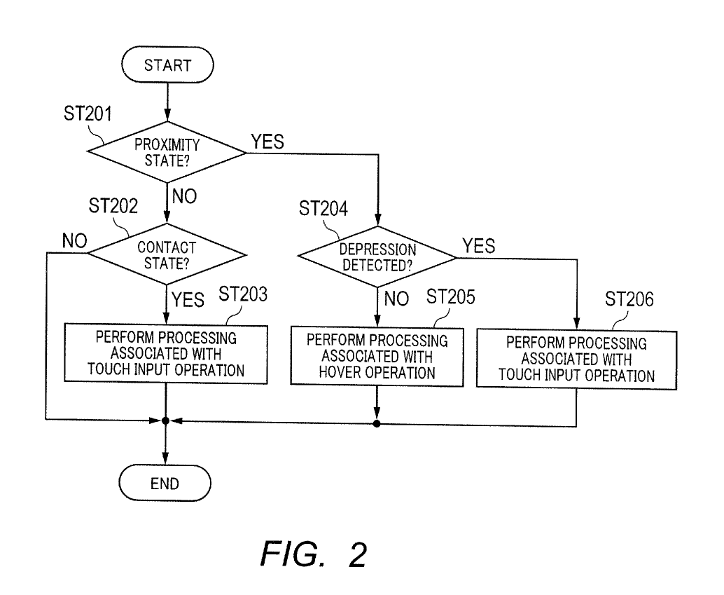

Operation of input apparatus 100 according to Embodiment 1 of the present invention will be described with reference to FIG. 2. In the description in FIG. 2, it is assumed that a hand is used as a conductive external object while a gloved hand is used as a non-conductive external object.

First, state determination section 105 determines whether or not a state determination result showing a proximity state has been inputted from coordinate acquiring section 102 (step ST201).

Upon determining that a state determination result showing a proximity state has not been inputted (step ST201: NO), state determination section 105 determines whether or not a state determination result showing a contact state has been inputted from coordinate acquiring section 102 (step ST202).

Upon determining that a state determination result showing a contact state has not been inputted (step ST202: NO), state determination section 105 ends the processing.

Meanwhile, when state determination section 105 determines that a state determination result showing a contact state has been inputted (step ST202: YES), touch coordinate processing section 106 performs processing associated with touch input operation (step ST203).

Furthermore, upon determining that a state determination result showing a proximity state has been inputted in step ST201 (step ST201: YES), state determination section 105 determines whether or not a detection result showing the presence of a depression has been inputted from depression acquiring section 104 (step ST204).

When state determination section 105 determines that a detection result showing the absence of a depression has been inputted (step ST204: NO), hover coordinate processing section 107 performs processing associated with hover operation (step ST205).

On the other hand, when state determination section 105 determines that a detection result showing the presence of a depression has been inputted (step ST204: YES), touch coordinate processing section 106 performs processing associated with touch input operation (step ST206). This allows input apparatus 100 to perform processing associated with touch input operation even when touch input operation is performed through a glove. Note that the processing associated with touch input operation may be the same as or different from the processing associated with the touch input operation in step ST203.

Note that input apparatus 100 performs the operation in FIG. 2 every time touch panel layer 101 is scanned.

<External Object State Determination Method>

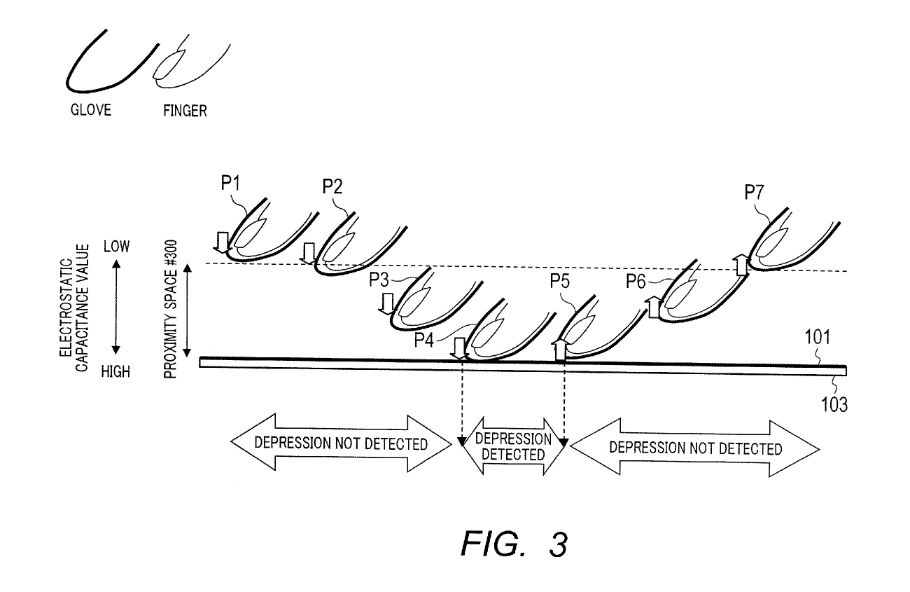

An external object state determination method according to Embodiment 1 of the present invention will be described with reference to FIG. 3. In FIG. 3, it is assumed that the external object that operates touch panel layer 101 is a gloved finger.

When an external object exists outside proximity space #300 (state shown by reference numerals P1 and P7 in FIG. 3), input apparatus 100 determines that coordinate acquiring section 102 cannot detect coordinates and that the state is neither contact state nor proximity state.

When an external object exists in proximity space #300, input apparatus 100 determines that coordinate acquiring section 102 detects coordinates and that the state is a proximity state. When depression sensor 103 is not pressed (state shown by reference numerals P2, P3, P5 and P6 in FIG. 3), coordinate acquiring section 102 and state determination section 105 in input apparatus 100 determine that the state is a proximity state. Hover coordinate processing section 107 thereby performs processing associated with hover operation.

In input apparatus 100, when an external object exists in proximity space #300 and depression sensor 103 is pressed (state shown by reference numeral P4 in FIG. 3), even if coordinate acquiring section 102 determines the state to be a proximity state, state determination section 105 determines the state to be a contact state. In this way, touch coordinate processing section 106 performs processing associated with touch input operation.

<Effects of Embodiment 1>

According to the present embodiment, it is possible to distinguish all operations such as the hover operation and touch input operation with a finger and the hover operation and touch input operation with a glove, thereby enabling a user-intended operation to be reliably performed.

### Embodiment 2

<Configuration of Input Apparatus>

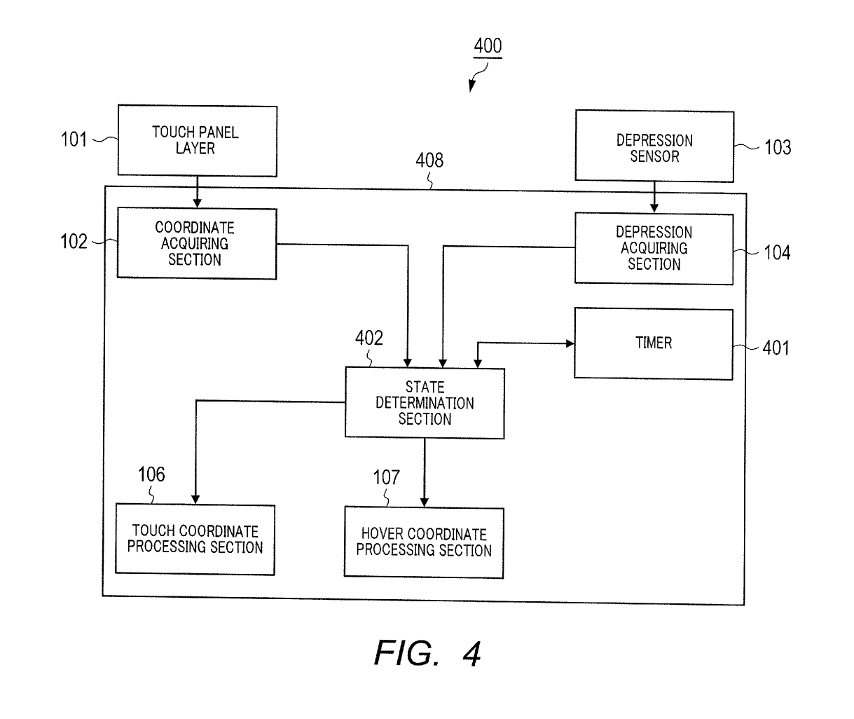

A configuration of input apparatus 400 according to Embodiment 2 of the present invention will be described with reference to FIG. 4.

Input apparatus 400 shown in FIG. 4 is different from input apparatus 100 according to Embodiment 1 shown in FIG. 1 in that timer 401 is added and that state determination section 105 is replaced by state determination section 402. Note that, in FIG. 4, the components identical to those in FIG. 1 will be assigned the same reference numerals and the description thereof will not be repeated.

Input apparatus 400 is mainly constructed of touch panel layer 101, coordinate acquiring section 102, depression sensor 103, depression acquiring section 104, touch coordinate processing section 106, hover coordinate processing section 107, timer 401, and state determination section 402.

Coordinate acquiring section 102 outputs the coordinate detection result and the state determination result to state determination section 402. Note that the configuration of coordinate acquiring section 102 other than that described above is the same as that of above-described Embodiment 1, and the description thereof will not be repeated.

Depression acquiring section 104 outputs the presence or absence of a depression to state determination section 402 as a detection result. Note that the configuration of depression acquiring section 104 other than that described above is the same as that of above-described Embodiment 1, so that the description thereof will not be repeated.

Timer 401 measures time until predetermined time T1 elapses under the control of state determination section 402. Timer 401 outputs a count-up signal to state determination section 402 when predetermined time T1 elapses.

Even when the state determination result inputted from coordinate acquiring section 102 shows a proximity state, if a detection result showing the presence of a depression is inputted from depression acquiring section 104, state determination section 402 determines the state to be a contact state. When the state determination result inputted from coordinate acquiring section 102 shows a proximity state and a detection result showing the absence of a depression is inputted from depression acquiring section 104, state determination section 402 determines the state to be a proximity state. Moreover, when the state determination result inputted from coordinate acquiring section 102 shows a contact state, state determination section 402 determines the state to be a contact state.

Upon determining the contact state, state determination section 402 notifies touch coordinate processing section 106 of the coordinates inputted from coordinate acquiring section 102. Upon determining the proximity state, state determination section 402 notifies hover coordinate processing section 107 of the coordinates inputted from coordinate acquiring section 102.

When the state determination result inputted from coordinate acquiring section 102 shows a proximity state and when a detection result showing the presence of a depression is inputted from depression acquiring section 104, state determination section 402 controls timer 401 so as to measure time until predetermined time T1 elapses after the time when the processing associated with the touch input operation starts. State determination section 402 notifies touch coordinate processing section 106 of coordinates until timer 401 indicates that predetermined time T1 elapses. When a count-up signal indicating that predetermined time T1 has elapsed is inputted from timer 401, state determination section 402 stops notifying touch coordinate processing section 106 of coordinates, whereas state determination section 402 notifies hover coordinate processing section 107 of coordinates. That is, state determination section 402 continues to notify touch coordinate processing section 106 of coordinates until predetermined time T1 elapses.

Touch coordinate processing section 106 performs processing associated with the touch input operation at the coordinates notified from state determination section 402.

Note that after being notified of the coordinates from state determination section 402, if notification of the coordinates is stopped, touch coordinate processing section 106 stops the processing associated with the touch input operation.

Hover coordinate processing section 107 performs processing associated with hover operation at the coordinates notified from state determination section 402.

<Operation of Input Apparatus>

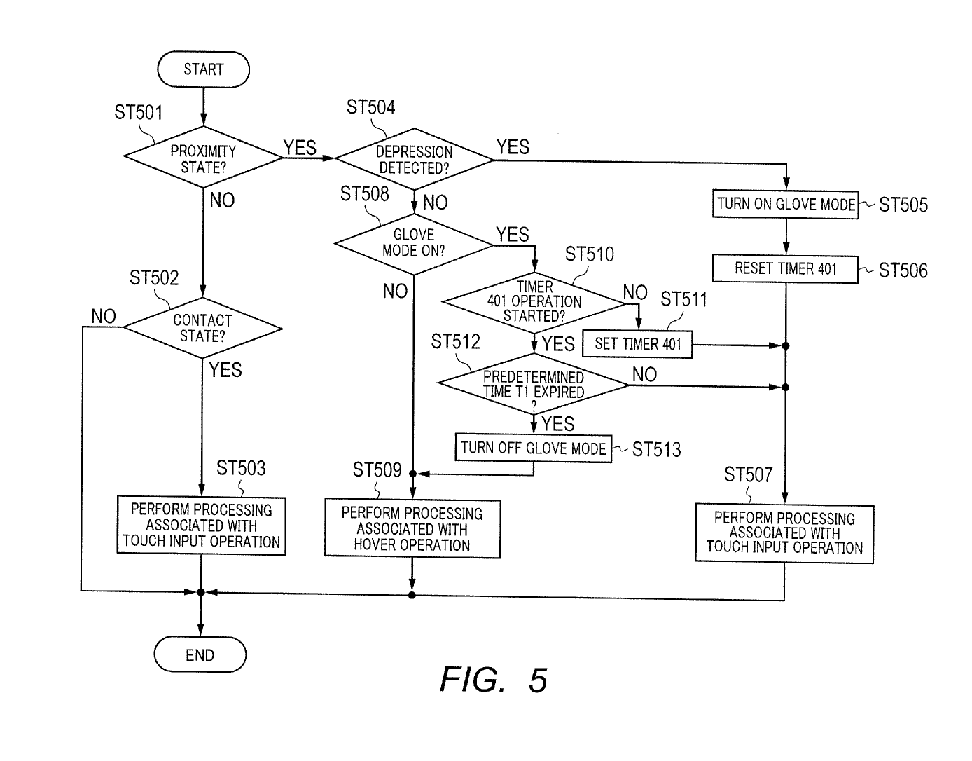

Operation of input apparatus 400 according to Embodiment 2 of the present invention will be described with reference to FIG. 5. In the description in FIG. 5, it is assumed that a hand is used as a conductive external object and a gloved hand is used as a non-conductive external object.

First, state determination section 402 determines whether or not a state determination result showing a proximity state has been inputted from coordinate acquiring section 102 (step ST501).

Upon determining that the state determination result showing a proximity state has not been inputted (step ST501: NO), state determination section 402 determines whether or not a determination result showing a contact state has been inputted from coordinate acquiring section 102 (step ST502).

Upon determining that the state determination result showing a contact state has not been inputted (step ST502: NO), state determination section 402 ends the processing.

On the other hand, when state determination section 402 determines that a state determination result showing a contact state has been inputted (step ST502: YES), touch coordinate processing section 106 performs processing associated with a touch input operation (step ST503).

Upon determining in step ST501 that a state determination result showing a proximity state has been inputted (step ST501: YES), state determination section 402 determines whether or not a detection result showing the presence of a depression has been inputted from depression acquiring section 104 (step ST504).

Upon determining that a detection result showing the presence of a depression has been inputted (step ST504: YES), state determination section 402 turns ON a glove mode (step ST505). Here, the glove mode refers to an operation mode in which processing is performed assuming that touch panel layer 101 is operated through a glove.

State determination section 402 resets timer 401 (step ST506).

Next, touch coordinate processing section 106 performs processing associated with touch input operation (step ST507).

On the other hand, upon determining in step ST504 that no depression has been detected (step ST504: NO), state determination section 402 determines whether or not the glove mode is ON (step ST508).

When state determination section 402 determines that the glove mode is OFF (step ST508: NO), hover coordinate processing section 107 performs processing associated with hover operation (step ST509).

On the other hand, upon determining that the glove mode is ON (step ST508: YES), state determination section 402 determines whether or not timer 401 has started a measurement operation (step ST510).

Upon determining that timer 401 has not started a measurement operation (step ST510: NO), state determination section 402 sets timer 401 and controls timer 401 so as to start measuring predetermined time T1 (step ST511). Then, touch coordinate processing section 106 performs processing in step ST507.

On the other hand, upon determining that timer 401 has already started a measurement operation (step ST510: YES), state determination section 402 determines whether or not predetermined time T1 measured by timer 401 has expired (step ST512).

Upon determining that predetermined time T1 has expired (step ST512: YES), state determination section 402 turns OFF the glove mode (step ST513). Then, hover coordinate processing section 107 performs processing in step ST509.

On the other hand, upon determining that predetermined time T1 has not expired (step ST512: NO), state determination section 402 performs processing in step ST507. Thus, input apparatus 400 causes touch coordinate processing section 106 to continue processing associated with touch input operation, while the glove mode is ON (predetermined time T1).

Note that input apparatus 400 performs the operation in FIG. 5 every time touch panel layer 101 is scanned.

<External object state determination method>

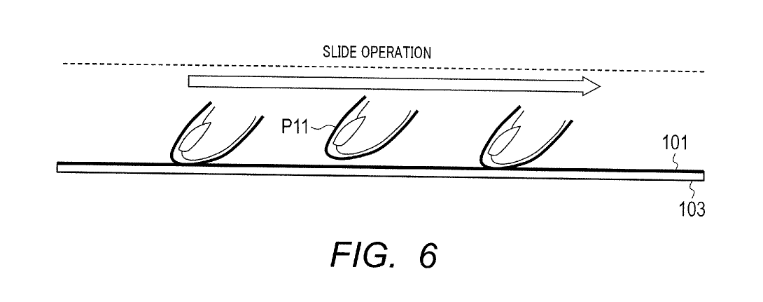

An external object state determination method according to Embodiment 2 of the present invention will be described with reference to FIG. 6.

FIG. 6 shows a state in which a gloved hand slides over touch panel layer 101 to thereby continue the touch input operation. In the case of FIG. 6, a depression force added from the user's hand to touch panel layer 101 is absorbed by the glove. Thus, there may be a case where only a depression force smaller than the depression force considered necessary to continue the touch input operation is actually added. As a result, the depression force may be reduced while the touch input operation continues (halfway during sliding) (state shown by reference numeral P11 in FIG. 6).

In the present embodiment, even when the depression force is reduced while the touch input operation continues after the glove mode is turned ON and depression acquiring section 104 cannot detect any depression, processing associated with the touch input operation is continued until predetermined time T1 elapses.

<Effects of Embodiment 2>

According to the present embodiment, in addition to the effects of above-described Embodiment 1, the processing associated with the touch input operation is continued until predetermined time T1 elapses after the glove mode is turned ON, and therefore even when the depression force on touch panel layer 101 is unintentionally reduced during the processing associated with the touch input operation, it is possible to reliably perform the user-intended operation.

According to the present embodiment, whether or not to turn the glove mode from ON to OFF is determined based on the time measured by timer 401, and it is thereby possible to continue the slide operation using a simple method.

### Embodiment 3

<Configuration of Input Apparatus>

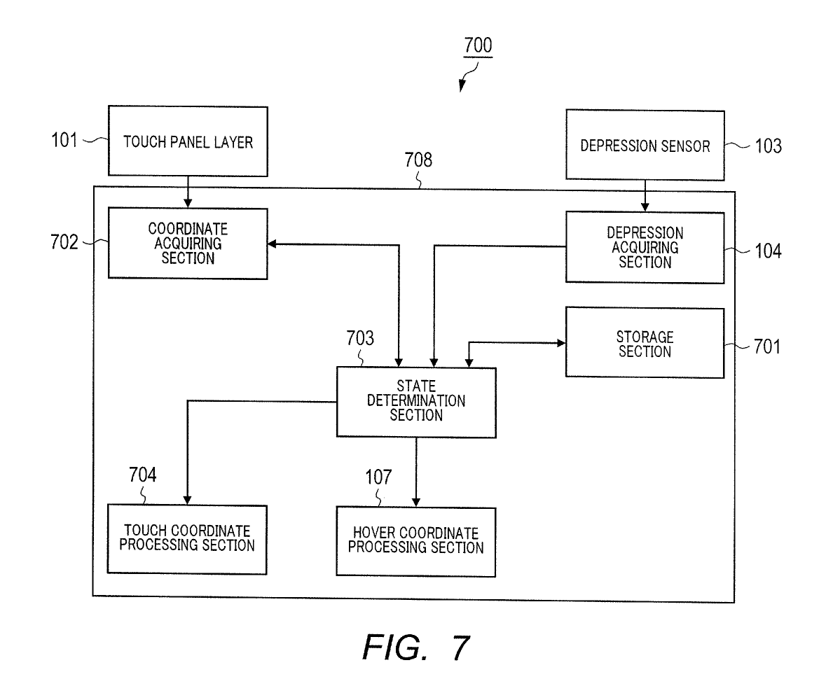

A configuration of input apparatus 700 according to Embodiment 3 of the present invention will be described with reference to FIG. 7.

Input apparatus 700 shown in FIG. 7 is different from input apparatus 100 according Embodiment 1 shown in FIG. 1 in that storage section 701 is added, that coordinate acquiring section 102 is replaced by coordinate acquiring section 702, and that state determination section 105 replaced by state determination section 703 and touch coordinate processing section 106 is replaced by touch coordinate processing section 704. Note that, in FIG. 7, the same components as those in FIG. 1 will be assigned identical reference numerals and the description thereof will not be repeated.

Input apparatus 700 mainly includes touch panel layer 101, depression sensor 103, depression acquiring section 104, hover coordinate processing section 107, storage section 701, coordinate acquiring section 702, state determination section 703 and touch coordinate processing section 704.

Storage section 701 stores intensity of a signal inputted from state determination section 703.

Coordinate acquiring section 702 detects coordinates touched by an external object or coordinates approached by an external object based on intensity of a signal outputted from each electrode of touch panel layer 101.

Coordinate acquiring section 702 determines a contact state and a proximity state of the external object based on the intensity of the signal outputted from each electrode of touch panel layer 101. Note that an example of a method of determining a contact state and a proximity state by coordinate acquiring section 702 is similar to that of above-described Embodiment 1, and therefore the description thereof will not be repeated.

Coordinate acquiring section 702 outputs the coordinate detection result and the state determination result to state determination section 703. Coordinate acquiring section 702 outputs the signal intensity detection result to state determination section 703 upon request from state determination section 703.

Upon detecting a depression, depression acquiring section 104 outputs the detection result to state determination section 703. Note that the configuration of depression acquiring section 104 other than that described above is the same as that of above-described Embodiment 1, and therefore the description thereof will not be repeated.

Even when the state determination result inputted from coordinate acquiring section 702 shows a proximity state, if a detection result showing the presence of a depression is inputted from depression acquiring section 104, state determination section 703 determines the state to be a contact state. On the other hand, when the state determination result inputted from coordinate acquiring section 702 shows a proximity state and a detection result showing the absence of a depression is inputted from depression acquiring section 104, state determination section 703 determines the state to be a proximity state. Moreover, when the state determination result inputted from coordinate acquiring section 702 shows a contact state, state determination section 703 determines the state to be a contact state.

Upon determining that the state is a contact state, state determination section 703 notifies touch coordinate processing section 704 of the coordinates inputted from coordinate acquiring section 702. Upon determining that the state is a proximity state, state determination section 703 notifies hover coordinate processing section 107 of the coordinates inputted from coordinate acquiring section 702.

When the state determination result inputted from coordinate acquiring section 702 shows a proximity state and the detection result showing the presence of a depression is inputted from depression acquiring section 104, state determination section 703 requests coordinate acquiring section 702 to output the signal intensity detection result when touch coordinate processing section 704 starts processing. State determination section 703 causes storage section 701 to store the signal intensity detection result acquired from coordinate acquiring section 702 as a reference value. Note that instead of the signal intensity when touch coordinate processing section 704 starts processing, state determination section 703 may cause storage section 701 to store the minimum intensity of a signal when touch coordinate processing section 704 performs processing (after depression acquiring section 104 detects a depression until it no longer detects any depression). It is thereby possible to also handle a case where the user has unintentionally reduced the depression force.

State determination section 703 determines whether or not to cause touch coordinate processing section 704 to continue processing based on a reference value stored in storage section 701. When state determination section 703 determines to cause touch coordinate processing section 704 to stop processing, state determination section 703 notifies touch coordinate processing section 704 that the processing is stopped. Here, the above-described reference value is stored every time touch coordinate processing section 704 starts processing, and is therefore a variable value.

Touch coordinate processing section 704 performs processing associated with touch input operation at coordinates notified from state determination section 703. Touch coordinate processing section 704 continues the processing associated with touch input operation until it receives a notification that the processing is stopped from state determination section 703.

Hover coordinate processing section 107 performs processing associated with hover operation at coordinates notified from state determination section 703.

<Operation of Input Apparatus>

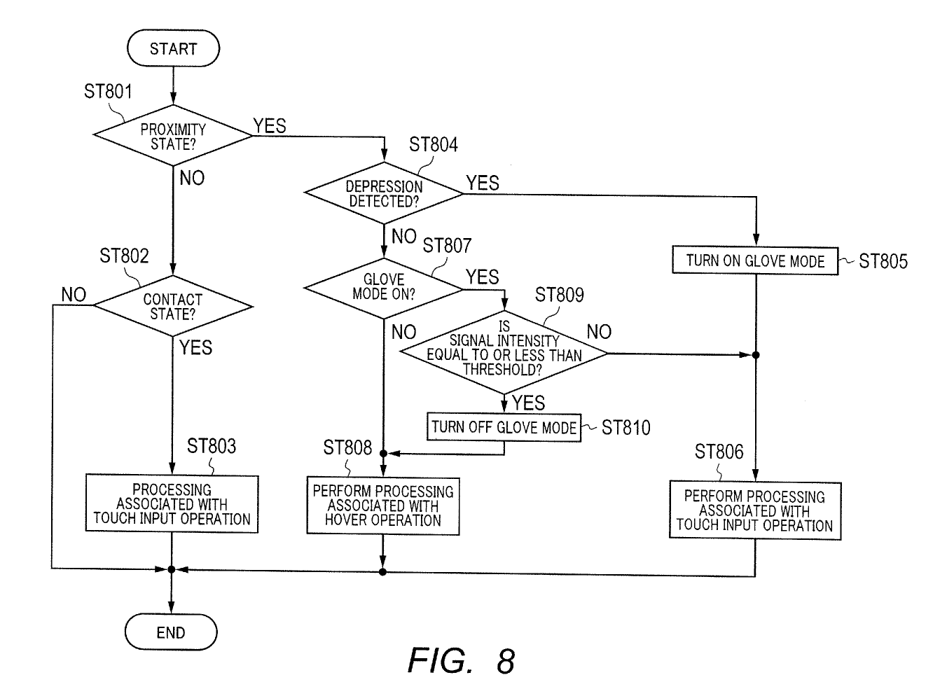

Operation of input apparatus 700 according to Embodiment 3 of the present invention will be described with reference to FIG. 8. In the description in FIG. 8, it is assumed that a hand is used as a conductive external object while a gloved hand is used as a non-conductive external object.

First, state determination section 703 determines whether or not a state determination result showing a proximity state has been inputted from coordinate acquiring section 702 (step ST801).

Upon determining that a state determination result showing a proximity state has not been inputted (step ST801: NO), state determination section 703 determines whether or not a state determination result showing a contact state has been inputted from coordinate acquiring section 702 (step ST802).

Upon determining that a state determination result showing a contact state has not been inputted (step ST802: NO), state determination section 703 ends the processing.

On the other hand, when state determination section 703 determines that a state determination result showing a contact state has been inputted (step ST802: YES), touch coordinate processing section 704 performs processing associated with touch input operation (step ST803).

Upon determining in step ST801 that a state determination result showing a proximity state has been inputted (step ST801: YES), state determination section 703 determines whether or not a detection result showing the presence of a depression has been inputted from depression acquiring section 104 (step ST804).

Upon determining that a detection result showing the presence of a depression has been inputted (step ST804: YES), state determination section 703 turns ON a glove mode (step ST805).

Next, touch coordinate processing section 704 performs processing associated with touch input operation (step ST806). In this case, state determination section 703 acquires a signal intensity detection result from coordinate acquiring section 702 and causes storage section 701 to store it as a reference value.

On the other hand, upon determining in step ST804 that a detection result showing the absence of a depression has been inputted (step ST804: NO), state determination section 703 determines whether or not the glove mode is ON (step ST807).

When state determination section 703 determines that the glove mode is OFF (step ST807: NO), hover coordinate processing section 107 performs processing associated with hover operation (step ST808).

On the other hand, upon determining that the glove mode is ON (step ST807: YES), state determination section 703 reads the reference value stored in storage section 701 and sets a threshold based on the read reference value. State determination section 703 sets, for example, a value equivalent to 80% of the reference value as a threshold.

State determination section 703 determines whether or not the intensity of a signal as a detection result acquired from coordinate acquiring section 702 is equal to or less than a threshold (step ST809).

When state determination section 703 determines that the signal intensity is greater than the threshold (step ST809: NO), touch coordinate processing section 704 performs processing in step ST806.

On the other hand, upon determining that the signal intensity is equal to or less than the threshold (step ST809: YES), state determination section 703 turns OFF the glove mode (step ST810). Hover coordinate processing section 107 then performs processing in step ST808.

Note that input apparatus 700 performs the operation in FIG. 8 every time touch panel layer 101 is scanned.

<External Object State Determination Method>

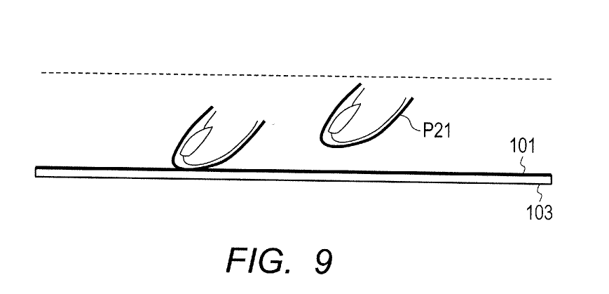

An external object state determination method according to Embodiment 3 of the present invention will be described with reference to FIG. 9.

When a touch input operation is in progress, a hand may be separated from touch panel layer 101 (state shown by reference numeral P21 in FIG. 9).

In the present embodiment, after the glove mode is turned ON, even when a depression force is reduced while the touch input operation continues and depression acquiring section 104 cannot detect any depression, touch coordinate processing section 704 continues processing associated with touch input operation unless the signal intensity falls to or below the threshold.

<Effects of Embodiment 3>

According to the present embodiment, in addition to the effects obtained in above-described Embodiment 1, processing associated with touch input operation continues after the glove mode is turned ON unless the signal intensity falls to or below a threshold, and therefore even when the depression force on touch panel layer 101 is unintentionally reduced when the processing associated with touch input operation is in progress, it is possible to reliably perform the user-intended operation.

According to the present embodiment, the signal intensity when the glove mode is turned ON is updated and used as a reference value every time the glove mode is turned ON, and therefore it is possible to set the threshold to an optimum value to be compared to the signal intensity.

According to the present embodiment, after the glove mode is turned ON, if the signal intensity falls to or below the threshold, the glove mode is turned OFF and processing associated with hover operation is performed, and therefore release of an external object from touch panel layer 101 can be determined by accurately following timing at which the external object is actually released from touch panel layer 101.

In the present embodiment, the reference value is set to a variable value, but the reference value may also be set to a fixed value.

In above-described Embodiment 1 to Embodiment 3, touch panel layer 101 is operated by a bare hand or a glove, but touch panel layer 101 may also be operated by a conductive external object other than the bare hand or a non-conductive external object other than the glove. Similar effects can be obtained in this case as well.

Furthermore, a case has been described in above-described Embodiment 1 to Embodiment 3 where the present invention is configured by hardware, but the present invention can also be implemented by software.

### Embodiment 4

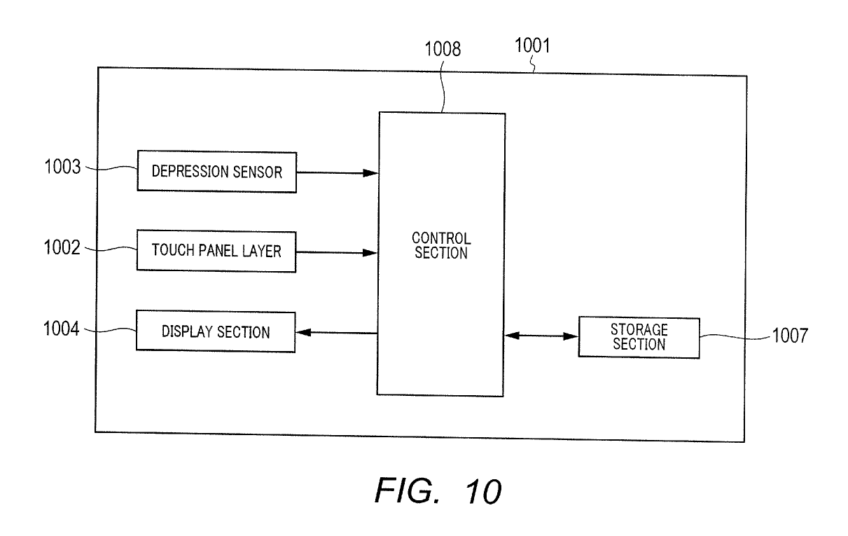

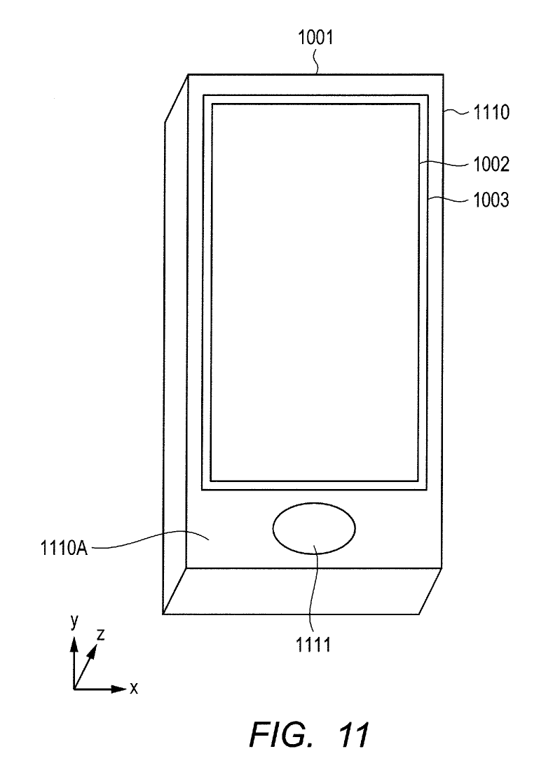

FIG. 10 is a block diagram illustrating a schematic configuration of electronic device 1001 according to an embodiment of the present invention. FIG. 11 is a perspective view illustrating an appearance of the electronic device in FIG. 10. Electronic device 1001 according to the present embodiment is an apparatus such as a portable radio device called “smartphone” to which the present invention applied. Note that, a section that functions as a radio device is omitted in the block diagram in FIG. 10.

In FIG. 10, electronic device 1001 according to the present embodiment is provided with touch panel layer 1002, depression sensor (corresponding to a depression detecting section) 1003, display section 1004, storage section 1007, and control section 1008. As shown in FIG. 11, electronic device 1001 according to the present embodiment includes oblong rectangular housing 1110. That is, when electronic device 1001 is viewed from above, housing 1110 looks an oblong rectangle.

Touch panel layer 1002, depression sensor 1003 and home key 1111 are arranged near front surface 1110A of housing 1110. Touch panel layer 1002 is disposed while being overlapped with depression sensor 1003 in such a way as to be placed on the front side of depression sensor 1003.

Home key 1111 is disposed on the front side of housing 1110 and right below touch panel layer 1002 and depression sensor 1003. That is, home key 1111 is disposed on the front side of housing 1110, along a long side direction of the oblong rectangle of housing 1110, at a position apart from touch panel layer 1002 and depression sensor 1003.

Though not shown in FIG. 11, protective glass (corresponding to a transparent member) is disposed on the front side of touch panel layer 1002 and display section 1004 is disposed more inside housing 1110 than depression sensor 1003. That is, touch panel layer 1002 is interposed between the protective glass and display section 1004.

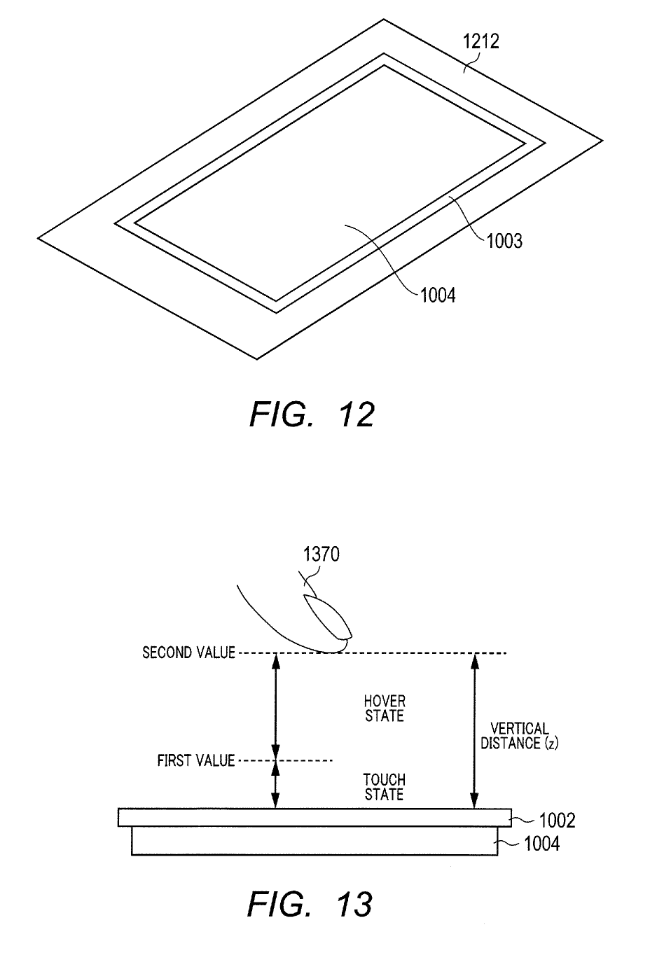

FIG. 12 illustrates an arrangement of protective glass 1212, depression sensor 1003 and display section 1004. As shown in FIG. 12, display section 1004 and depression sensor 1003 are arranged in this order below glass 1212. Glass 1212 has a planar shape and has a predetermined transmittance for visible light and allows visible light corresponding to display contents of display section 1004 to pass through glass 1212. At least part of glass 1212 is disposed so as to be exposed from housing 1110 and the rest of glass 1212 is disposed inside housing 1110. Note that touch panel layer 1002 is disposed so as to be in contact with an undersurface of glass 1212.

Touch panel layer 1002 and display section 1004 have a planar shape having a slightly smaller area than front surface 1110A of housing 1110 and are formed in an oblong rectangular shape in a plan view. In this case, the area of display section 1004 is slightly smaller than the area of touch panel layer 1002.

Touch panel layer 1002 is an electrostatic-capacitance touch panel layer that can operate at a height within a predetermined range (referred to as “hover operation”) without an indicator (a skin part of a finger or a special pen or the like which have a predetermined conductivity, and mainly referred to as “finger” in the present embodiment) touching the panel surface of touch panel layer 1002.

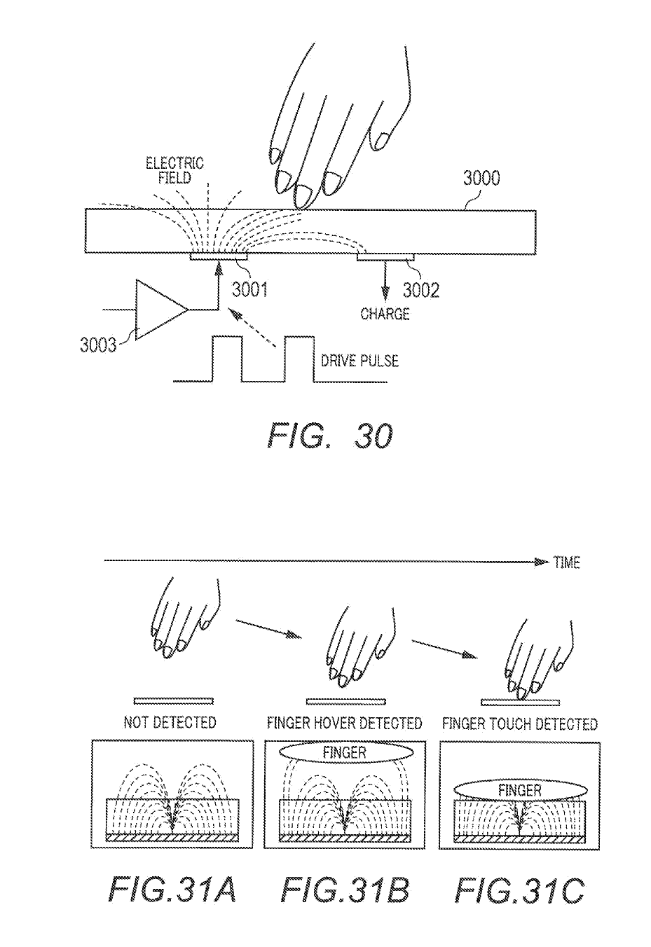

Electrostatic-capacitance touch panel layer 1002 is provided with transmission electrode 3001 and reception electrode 3002 as shown in FIG. 30, and these electrodes are arranged apart from each other on an undersurface of tabular dielectric 3000 (glass or the like). A drive pulse based on a transmission signal is applied to transmission electrode 3001. When the drive pulse is applied to transmission electrode 3001, an electric field is generated from transmission electrode 3001, and when a finger enters this electric field, the number of electric flux lines between transmission electrode 3001 and reception electrode 3002 decreases and the change in the number appears as a change in charge in reception electrode 3002.

Touch panel layer 1002 detects the finger from a received signal in accordance with the change in charge in reception electrode 3002, detects coordinates (x, y) of the finger along the surface of display section 1004 and also detects a vertical distance (z) from the finger to touch panel 1002, and outputs the detected two-dimensional coordinates (x, y) and vertical distance (z) to control section 1008.

FIGS. 31A-31C show states where the fingers are detected when the fingers are gradually brought into proximity to an electrostatic-capacitance touch panel. FIG. 31A shows a state where the fingers do not enter an electric field, that is, the fingers are not detected. FIG. 31B shows a state where the fingers enter the electric field, but do not touch the touch panel, that is, hover operation is detected. FIG. 31C shows a state where the fingers enter the electric field and touch the touch panel, that is, touch operation is detected.

It should be noted that operation performed by the fingers in a glove touching the touch panel corresponds to the state shown in FIG. 31B because the fingers do not directly touch the touch panel.

Returning to FIG. 12, depression sensor 1003 detects deformation of at least protective glass 1212 to thereby detect a depression of the finger or the like to glass 1212.

Display section 1004 has a rectangular shape and is used as a display for operating electronic device 1001 or for displaying images or the like. Display section 1004 includes an LCD (Liquid Crystal Display) and a backlight and is disposed on the back side of touch panel layer 1002 with its LCD side facing the touch panel layer 1002 side.

Note that although display section 1004 includes an LCD, the display device included in display section 1004 is not limited to LCDs. Display section 1004 may include a different display device such as an organic EL (Electro Luminescence) or electronic paper display other than LCDs.

Returning to FIG. 10, storage section 1007 includes a volatile memory such as a DRAM (Dynamic Random Access Memory) and stores a setting made by the user to use electronic device 1001. Control section 1008 is configured to control the components of electronic device 1001 and includes a CPU (Central Processing Unit), a ROM (Read Only Memory), a RAM (Random Access Memory) and an interface circuit. The ROM stores a program for controlling the CPU while the RAM is used during operating of the CPU.

Here, a positional relationship between a finger which is an indicator of touch panel layer 1002 (can be anything as long as the indicator has a predetermined conductivity and may be, for example, part of skin or a special pen) will be described. FIG. 13 illustrates a positional relationship between touch panel layer 1002 and finger 1370 which is an indicator. As shown in FIG. 13, a state in which a vertical distance (z) from finger 1370 above touch panel layer 1002 is equal to or less than a first value is a touch state. A state in which the vertical distance (z) from finger 1370 to touch panel layer 1002 is equal to or less than a second value which is greater than the first value is a hover state.

Control section 1008 assumes the two-dimensional coordinates (x, y) as effective coordinates at least in cases shown in (1) to (3) below.

(1) When the vertical distance (z) outputted from touch panel layer 1002 is equal to or less than the first value (that is, in the case of a touch state), at least the two-dimensional coordinates (x, y) outputted from touch panel layer 1002 are treated as effective coordinates.

(2) When the vertical distance (z) outputted from touch panel layer 1002 is equal to or less than the first value (that is, in the case of a touch state) and depression sensor 1003 detects predetermined deformation, at least the two-dimensional coordinates (x, y) outputted from touch panel layer 1002 are treated as effective coordinates.

(3) When the vertical distance (z) outputted from touch panel layer 1002 is greater than the first value but not greater than the second value (that is, in the case of a hover state) and depression sensor 1003 detects predetermined deformation, at least the two-dimensional coordinates (x, y) outputted from touch panel layer 1002 are treated as effective coordinates.

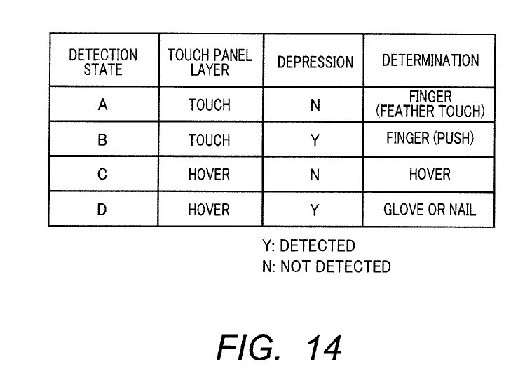

FIG. 14 illustrates a table including determinations made by control section 1008 when touch panel layer 1002 and depression sensor 1003 are in their respective detection states. In FIG. 14, “Y” indicates “detected” and “N” denotes “not detected.”

Detection state A is a state in which touch panel layer 1002 has detected a touch and depression sensor 1003 has not detected deformation of glass 1212. In this state, control section 1008 can detect the finger (a feather touch).

Detection state B is a state in which touch panel layer 1002 has detected a touch and depression sensor 1003 has detected deformation of glass 1212. In this state, control section 1008 can detect the finger (a push).

Detection state C is a state in which touch panel layer 1002 has detected only hover. In this state, control section 1008 determines the state to be hover.

Detection state D is a state in which touch panel layer 1002 has detected hover and depression sensor 1003 has detected deformation of glass 1212. In this state, control section 1008 can detect a glove or nail.

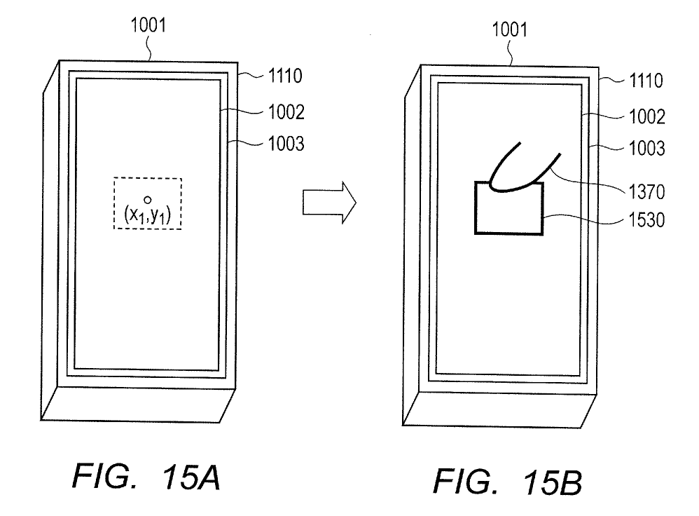

Returning to FIG. 10, display section 1004 performs a display operation corresponding to effective two-dimensional coordinates (x, y). For example, display section 1004 displays an indicator or icon. FIGS. 15A and 15B illustrate an example where an icon is displayed. As shown in FIG. 15A, when two-dimensional coordinates (x₁, y₁) are effective coordinates, icon 1530 is displayed as shown in FIG. 15B. Note that an indicator (not shown) may be displayed in correspondence with the effective coordinates (x, y). When the indicator and the icon overlap each other, the icon may be made to be selectable, and further, a function corresponding to the icon may also be started when finger 1370 approaches touch panel layer 1002 and moves to a position corresponding to a first value or less of the vertical distance in this state. The indicator or icon is displayed or the function corresponding to the icon is started by control section 1008.

Note that the above-described first value of the vertical distance may be 0 (zero).

Next, operation of electronic device 1001 according to the present embodiment will be described.

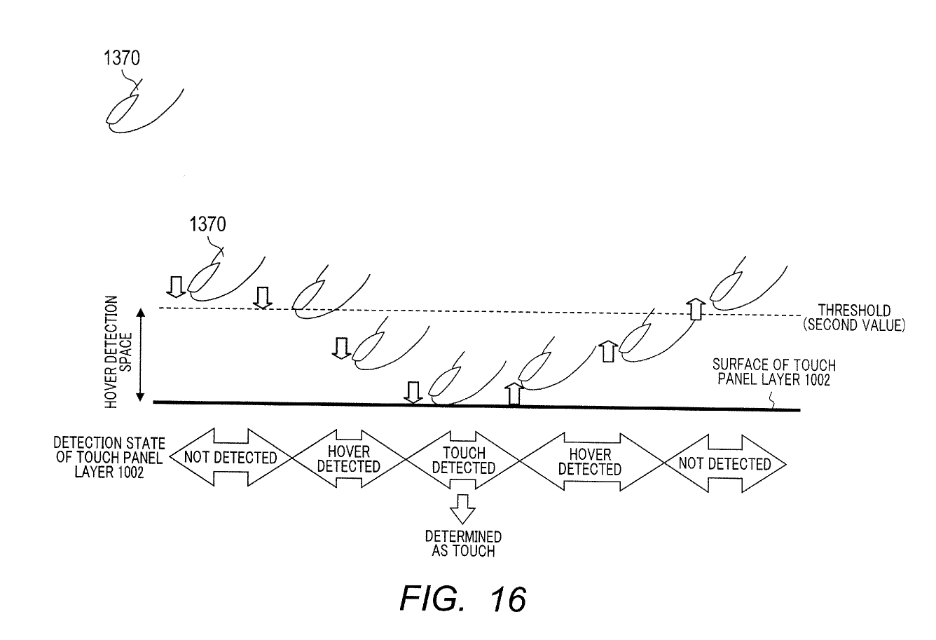

FIG. 16 illustrates detection states of finger 1370 when finger 1370 is gradually brought into proximity with touch panel layer 1002, comes into contact with touch panel layer 1002 and then is gradually separated from touch panel layer 1002.

In FIG. 16, when the vertical distance (z) between finger 1370 and touch panel layer 1002 exceeds a threshold (second value), the detection state of touch panel layer 1002 becomes “not detected.” After that, when the vertical distance (z) falls to or below the threshold (second value), the detection state of touch panel layer 1002 becomes “hover detected.” After that, when finger 1370 approaches touch panel layer 1002 so close that it touches the surface of touch panel layer 1002 (actually the surface of glass 1212), the detection state of touch panel layer 1002 becomes “touch detected.” At this time control section 1008 determines a “touch.” After that, when finger 1370 is separated from the surface of touch panel layer 1002, the detection state of touch panel layer 1002 becomes “hover detected.” This hover detected state continues until the vertical distance (z) between finger 1370 and touch panel layer 1002 exceeds the threshold (second value), and when the vertical distance (z) exceeds the threshold (second value), the detection state becomes “not detected.”

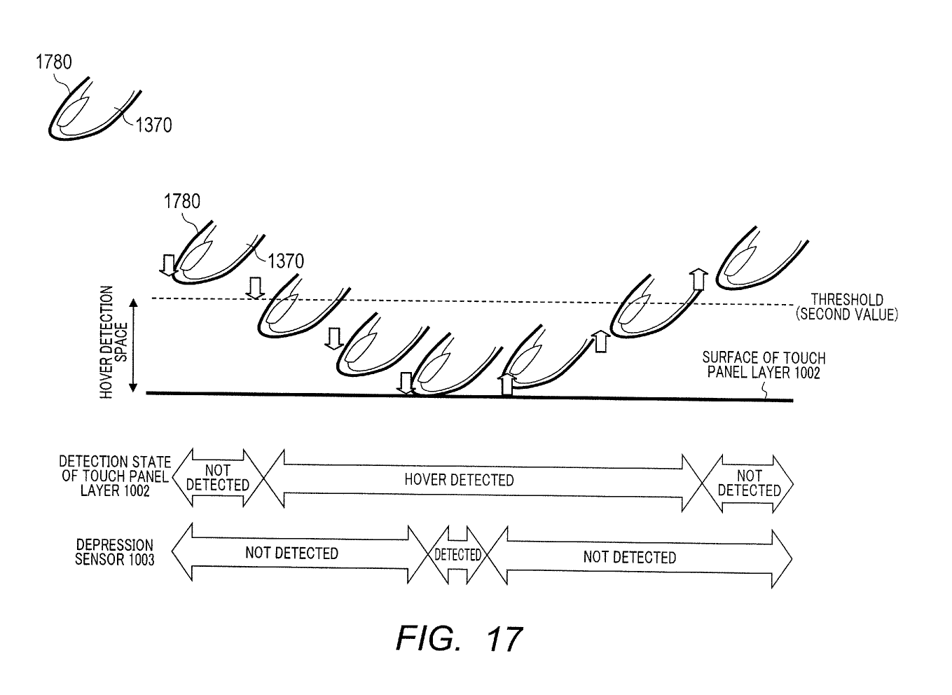

FIG. 17 illustrates detection states of finger 1370 in glove 1780 when finger 1370 is gradually brought into proximity with touch panel layer 1002, comes into contact with touch panel layer 1002 and then is gradually separated from touch panel layer 1002.

In FIG. 17, when the vertical distance (z) between finger 1370 and touch panel layer 1002 exceeds the threshold (second value), the detection state of touch panel layer 1002 becomes “not detected.” After that, when the vertical distance (z) falls to or below the threshold (second value), the detection state of touch panel layer 1002 becomes “hover detected.” The “hover detected” state continues even when glove 1780 comes into contact with the surface of touch panel layer 1002. Furthermore, this hover detected state continues until the vertical distance (z) between finger 1370 and touch panel layer 1002 exceeds the threshold (second value) and when the vertical distance exceeds the threshold (second value), the detection state of touch panel layer 1002 becomes “not detected.”

On the other hand, the detection state of depression sensor 1003 becomes “not detected” after the vertical distance (z) between finger 1370 and touch panel layer 1002 exceeds the threshold (second value) until glove 1780 comes into contact with touch panel layer 1002. After that, when glove 1780 touches the surface of touch panel layer 1002, the detection state of depression sensor 1003 becomes “detected.” Then, when glove 1780 is separated from the surface of touch panel layer 1002, the detection state of depression sensor 1003 becomes “not detected.”

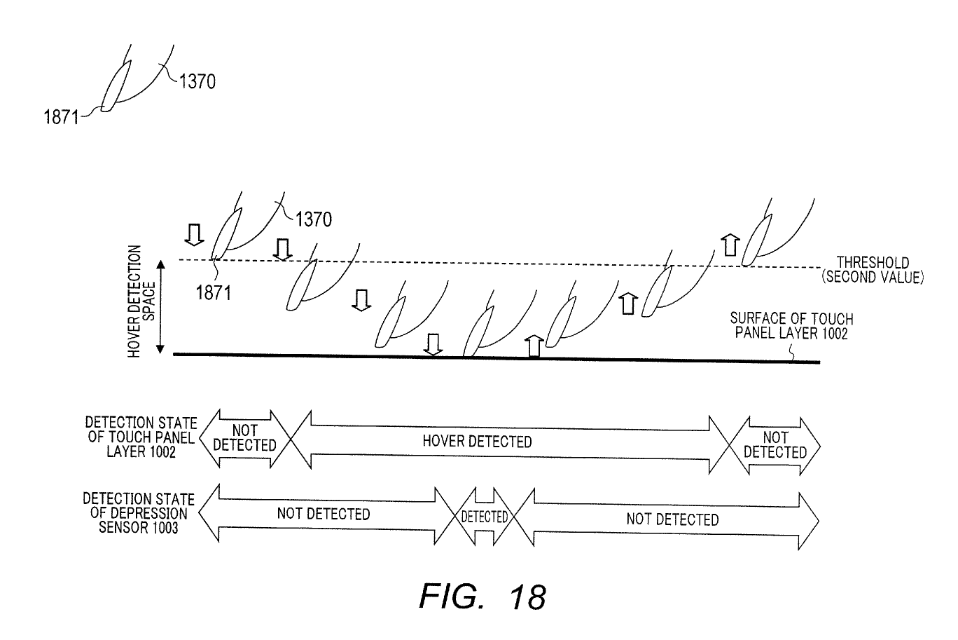

FIG. 18 illustrates detection states of nail 1871 when nail 1871 is gradually brought into proximity with touch panel layer 1002, comes into contact with touch panel layer 1002 and then is gradually separated from touch panel layer 1002.

In FIG. 18, when the vertical distance (z) between finger 1370 and touch panel layer 1002 exceeds the threshold (second value), the detection state of touch panel layer 1002 becomes “not detected.” When the vertical distance (z) falls to or below the threshold (second value), the detection state of touch panel layer 1002 becomes “hover detected.” The hover detected state continues even when nail 1871 touches the surface of touch panel layer 1002. Furthermore, the hover detected state continues until the vertical distance (z) between finger 1370 and touch panel layer 1002 exceeds the threshold (second value) and when the vertical distance exceeds the threshold (second value), the detection state of touch panel layer 1002 becomes “not detected.”

On the other hand, the detection state of depression sensor 1003 becomes “not detected” after the vertical distance (z) between finger 1370 and touch panel layer 1002 exceeds the threshold (second value) until nail 1871 comes into contact with touch panel layer 1002. When nail 1871 touches the surface of touch panel layer 1002, the detection state of depression sensor 1003 becomes “detected.” When nail 1871 is separated from the surface of touch panel layer 1002, the detection state of depression sensor 1003 becomes “not detected.”

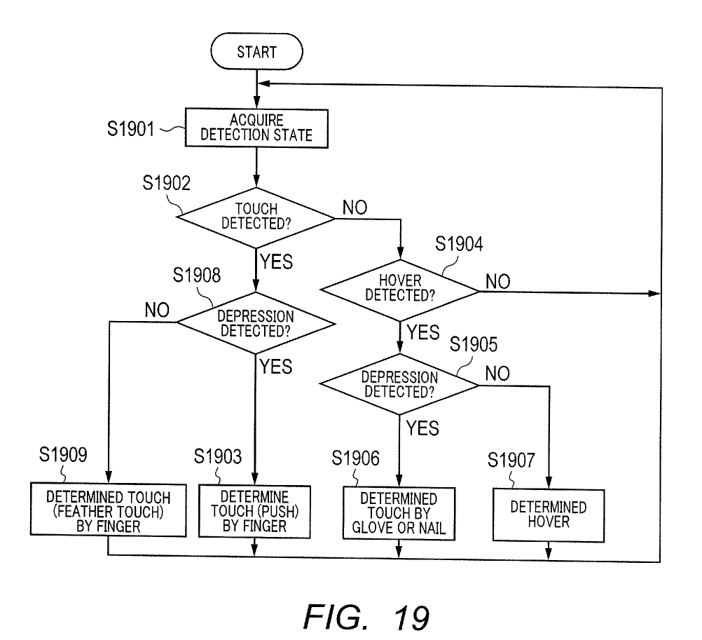

Next, FIG. 19 is a flowchart illustrating indicator determination processing of electronic device 1001 according to the present embodiment. In FIG. 19, control section 1008 fetches respective outputs of touch panel layer 1002 and depression sensor 1003, and thereby acquires the detection state (step S1901). Upon acquiring the detection state, control section 1008 determines whether or not the state is “touch detected” (step S1902), and when control section 1008 determines “touch detected” (that is, the determination in step S1902 results in “YES”), control section 1008 determines whether or not the state is “depression detected” (step S1908).

When the determination in step S1908 shows that the state is not “depression detected” (that is, determination in step S1908 results in “NO”), control section 1008 determines a touch (feather touch) by finger 1370 and also assumes the two-dimensional coordinates (x, y) to be effective coordinates (step S1909). Control section 1008 then returns to step S1901.

When the determination in step S1908 is “depression detected” (that is, determination in step S1908 results in “YES”), control section 1008 determines a touch (push) by finger 1370 and also assumes the two-dimensional coordinates (x, y) to be effective coordinates (step S1903). Control section 1008 then returns to step S1901.

When control section 1008 determines, in step S1902, that the detection state is not “touch detected” (that is, the determination in step S1902 results in “NO”), control section 1008 determines whether or not the detection state is “hover detected” (step S1904), and upon determining that the detection state is not “hover detected” (that is, the determination in step S1904 results in “NO”), control section 1008 returns to step S1901. In contrast, when the determination is “hover detected” (that is, the determination in step S1904 results in “YES”), control section 1008 determines whether or not the detection state is “depression detected” (step S1905). When the determination is “depression detected” (that is, the determination in step S1905 results in “YES”), control section 1008 determines a touch by glove 1780 or nail 1871 and also assumes the two-dimensional coordinates (x, y) to be effective coordinates (step S1906). After determining a touch by glove 1780 or nail 1871, control section 1008 returns to step S1901.

When the determination in step S1905 shows that the state is not “depression detected” (that is, the determination in step S1905 results in “NO”), control section 1008 determines simple hover (step S1907). After that, control section 1008 returns to step S1901. Note that in step S1907, the two-dimensional coordinates (x, y) may or may not be assumed to be effective coordinates.

Thus, electronic device 1001 according to the present embodiment is provided with touch panel layer 1002 and depression sensor 1003, and when touch panel layer 1002 detects a touch, electronic device 1001 determines the touch to be a touch by a finger, assumes the two-dimensional coordinates outputted from touch panel layer 1002 at that time to be effective coordinates, and, when touch panel layer 1002 detects hover and depression sensor 1003 detects predetermined deformation, electronic device 1001 determines the touch to be a touch by a gloved finger or a nail, and assumes the two-dimensional coordinates outputted from touch panel layer 1002 to be effective coordinates, and can thereby detect which part of the touch panel is pressed not only in the case where the touch panel is touched with a finger but also in the case where the touch panel is touched with a gloved finger or touched with a long nail.

That is, in the case where protective glass 1212 is touched with a tip of a long nail or a tip of a gloved finger or the like, that is, even in the case where the vertical distance is greater than the first value, if depression sensor 1003 detects predetermined deformation, two-dimensional coordinates are assumed to be effective coordinates, and therefore two-dimensional coordinates can be inputted with the tip of a nail or the tip of a gloved finger as well.

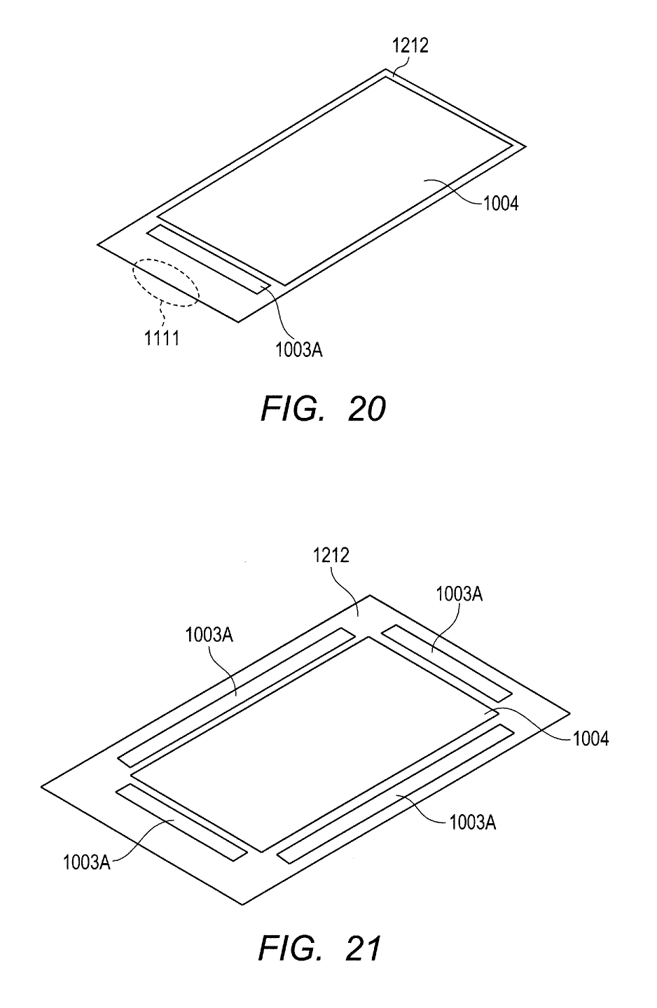

Note that, in electronic device 1001 according to the present embodiment, rectangular depression sensor 1003 which is slightly greater than display section 1004 is disposed below display section 1004, but the present invention is not limited to this case. For example, as shown in FIG. 20, band-shaped depression sensor 1003A may be disposed along one of two short sides of display section 1004. As shown in FIG. 20, home key 1111 is provided on one short side of the rectangle of display section 1004 and depression sensor 1003A is disposed along this short side. Thus, disposing depression sensor 1003A using a space peripheral to home key 1111 allows effective utilization of the space.

Furthermore, as shown in FIG. 21, four band-shaped depression sensors 1003A may be used, arranged along the four sides of display section 1004 respectively or arranged along one side, two sides or three sides. In this case, since display section 1004 has a rectangular shape, it goes without saying that depression sensors 1003A arranged along both long sides of display section 1004 are longer than depression sensors 1003A arranged along both short sides. Disposing band-shaped depression sensor 1003A in proximity to display section 1004 allows effective utilization of space.

Furthermore, as shown in the flowchart in FIG. 19, electronic device 1001 according to the present embodiment can determine a touch with a finger (feather touch)/touch (push) with a finger/touch with a glove or nail/hover. In addition, the display operation of display section 1004 may be switched in accordance with these determination results. For example, the determination results may be displayed on display section 1004 using icons or the like.

Electronic device 1001 according to the present embodiment causes the ROM to store a program describing the processing indicated by the flowchart in FIG. 19, but it is also possible to store the program in a storage medium such as a magnetic disk, optical disk, magneto-optical disk or flash memory, distribute the program, and save the program in a server (not shown) on a network such as the Internet so as to be downloadable using a telecommunication channel.

Electronic device 1001 according to the present embodiment is the present invention applied to a portable radio device called “smartphone.” The present invention is, however, not limited to a portable radio device, but is also applicable to operation panels for household electrical appliances such as microwave oven and refrigerator, navigation operation panels for vehicles, or operation panels for HEMS (Home Energy Management System) and BEMS (Building Energy Management System) or the like.

In electronic device 1001 according to the present embodiment, touch panel layer 1002, display section 1004, and depression sensor 1003 are arranged in that order below glass 1212, but a variety of shapes and arrangements may be considered for these components. Application examples thereof will be shown below.

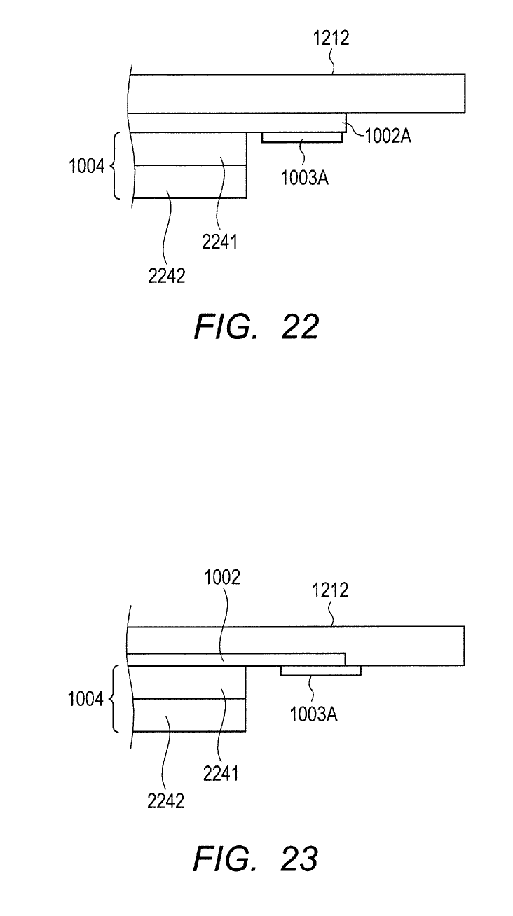

(1) FIG. 22 illustrates an arrangement of glass, a touch panel layer, a depression sensor and a display section as application example 1. Application example 1 shown in FIG. 22 uses a glass touch panel layer (which is referred to as “touch panel layer 1002A”), uses band-shaped depression sensor 1003A shown in FIG. 20 or FIG. 21 as a depression sensor, disposes touch panel layer 1002A on the undersurface side of protective glass 1212, disposes depression sensor 1003A on the periphery of the undersurface side of touch panel layer 1002A, and disposes display section 1004 on the undersurface side of touch panel layer 1002A and at a position away from depression sensor 1003A. Display section 1004 includes LCD 2241 and backlight 2242, with the LCD 2241 side disposed so as to face the touch panel layer 1002A side.

(2) FIG. 23 illustrates an arrangement of glass, a touch panel layer, a depression sensor and a display section as application example 2. Application example 2 shown in FIG. 23 disposes touch panel layer 1002 so as to be embedded on the undersurface side of protective glass 1212. That is, protective glass 1212 and touch panel layer 1002 are integrated into one piece. Depression sensor 1003A is disposed over the undersurface sides of glass 1212 and touch panel layer 1002, and display section 1004 is disposed on the undersurface side of touch panel layer 1002 and at a position away from depression sensor 1003A. As in the case of aforementioned application example 1, display section 1004 includes LCD 2241 and backlight 2242 and is disposed in such a way that LCD 2241 faces the touch panel layer 1002.

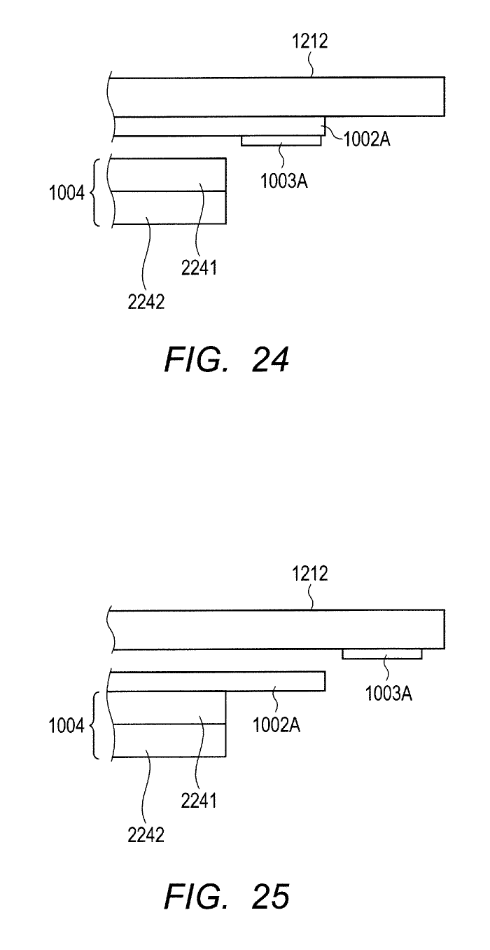

(3) FIG. 24 illustrates an arrangement of glass, a touch panel layer, a depression sensor and a display section as application example 3. Application example 3 shown in FIG. 24 disposes glass touch panel layer 1002A on the undersurface side of protective glass 1212, disposes depression sensor 1003A on the periphery of the undersurface side of touch panel layer 1002A, and further disposes display section 1004 below touch panel layer 1002A and at a position away from touch panel layer 1002A. As in the case of aforementioned application example 1, display section 1004 includes LCD 2241 and backlight 2242, and is disposed in such a way that the LCD 2241 side faces touch panel layer 1002A.

That is, depression sensor 1003A, touch panel layer 1002A, and protective glass 1212 are arranged at predetermined distances from display section 1004.

(4) FIG. 25 illustrates an arrangement of glass, a touch panel layer, a depression sensor and a display section as application example 4. Application example 4 shown in FIG. 25 disposes depression sensor 1003A on the periphery of the undersurface side of protective glass 1212, disposes glass touch panel layer 1002A below glass 1212 and at a position away from glass 1212 and further disposes display section 1004 on the undersurface side of touch panel layer 1002A. Display section 1004 includes LCD 2241 and backlight 2242 and is disposed in such a way that the LCD 2241 faces the touch panel layer 1002A as in the case of aforementioned application example 1.

That is, depression sensor 1003A and protective glass 1212 are arranged at predetermined distances from touch panel layer 1002A and display section 1004.

In the arrangement shown in FIG. 24 or FIG. 25, display section 1004 can be separated from protective glass 1212 (e.g., 5 mm to 15 mm). The arrangement is effective, for example, when protective glass 1212 has a certain amount of recessed and protruding parts or a certain degree of curvature, and when display section 1004 is rigid and it is preferable to avoid glass 1212 from contacting recessed and protruding portions or the like. Alternatively, it is also possible to dispose display section 1004 inside one side (e.g., the door) of a refrigerator and dispose protective glass 1212 having a certain degree of curvature on the side at a position corresponding to display section 1004. Alternatively, it is also possible to dispose a large screen (e.g., 50-inch type) display section 1004 inside a show window and use the show window glass (glass belonging to a building) as protective glass 1212.

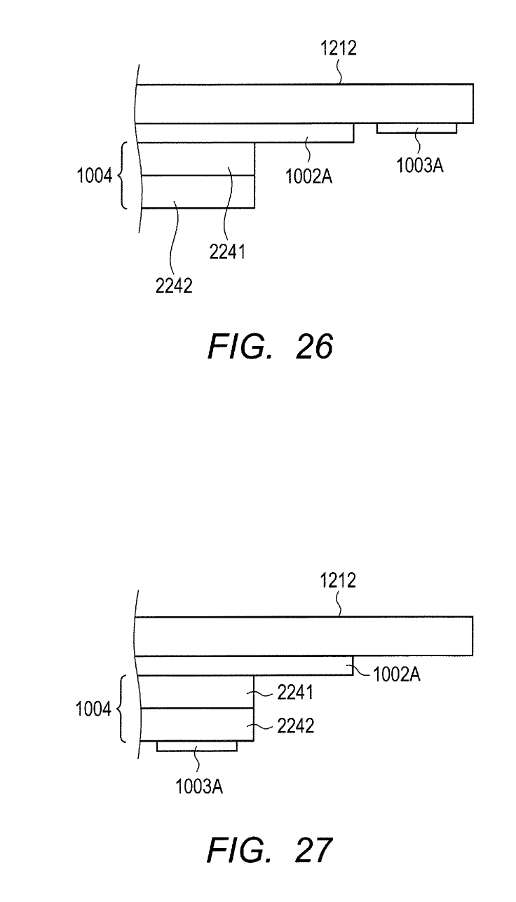

(5) FIG. 26 illustrates an arrangement of glass, a touch panel layer, a depression sensor and a display section as application example 5. Application example 5 shown in FIG. 26 disposes touch panel layer 1002A on an undersurface side of protective glass 1212, disposes depression sensor 1003A at a position away from touch panel layer 1002A (on the periphery of glass 1212) and further disposes display section 1004 on the undersurface side of touch panel layer 1002A. Display section 1004 includes LCD 2241 and backlight 2242 and is disposed in such a way LCD 2241 faces the touch panel layer 1002A as in the case of aforementioned application example 1.

(6) FIG. 27 illustrates an arrangement of glass, a touch panel layer, a depression sensor and a display section as application example 6. Application example 6 shown in FIG. 27 disposes touch panel layer 1002A on the undersurface side of protective glass 1212, disposes display section 1004 on the undersurface side of touch panel layer 1002A and further disposes depression sensor 1003A on the periphery of the undersurface side of display section 1004. Display section 1004 includes LCD 2241 and backlight and is disposed in such a way that LCD 2241 faces touch panel layer 1002A as in the case of aforementioned application example 1.

Furthermore, the position where depression sensor 1003A is disposed is not limited to the undersurface side of display section 1004, and depression sensor 1003A may also be disposed on the top surface side (not shown) of the display section, on one side (not shown) of display section 1004 or inside display section 1004 (not shown).

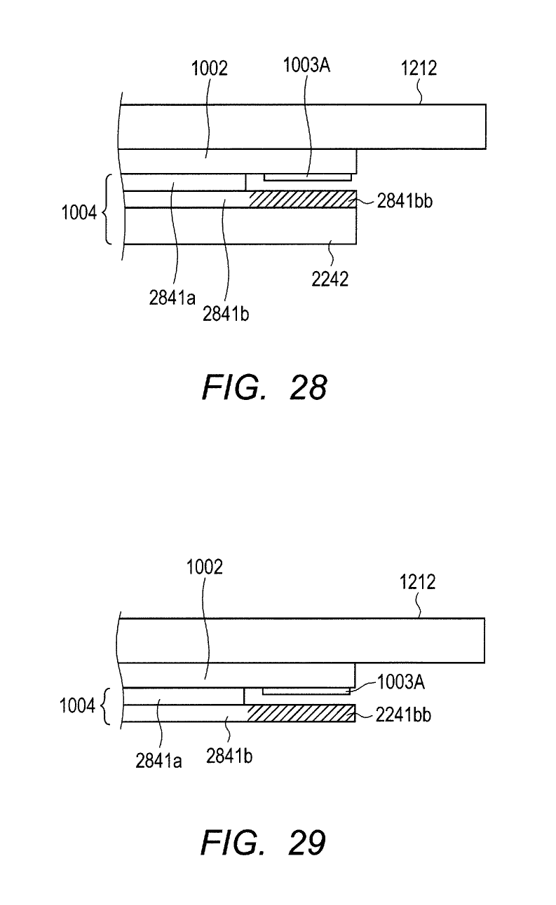

(7) FIG. 28 illustrates an arrangement of glass, a touch panel layer, a depression sensor and a display section as application example 7. Application example 7 shown in FIG. 28 uses protective glass 1212 as a first transparent member, adopts display section 1004 including at least second transparent member 2841a having a planar shape and third transparent member 2841b disposed while being overlapped with second transparent member 2841a with a liquid crystal interposed between second transparent member 2841a and third transparent member 2841b.

Furthermore, application example 7 disposes second transparent member 2841a on the undersurface side of touch panel layer 1002 at a position closer to the touch panel layer 1002 side than third transparent member 2841b, disposes part of third transparent member 2841b at end 2841bb of display section 1004 so as to protrude outward from second transparent member 2841a, and disposes depression sensor 1003A on a part of touch panel layer 1002 corresponding to protruding end 2841bb of third transparent member 2841b.

According to this arrangement, depression sensor 1003A is disposed on the part corresponding to protruding end 2841bb of third transparent member 2841b, which eliminates the necessity for an additional space to dispose depression sensor 1003A and allows efficient use of the space in electronic device 1001.

(8) FIG. 29 illustrates an arrangement of glass, a touch panel layer, a depression sensor and a display section as application example 8. Application example 8 shown in FIG. 29 is a modification example of aforementioned application example 7, and while application example 7 uses liquid crystal display section 1004, application example 8 uses organic EL display section 1004A. Use of an organic EL display eliminates the necessity for a backlight.

According to this arrangement as in the case of application example 7, depression sensor 1003A is disposed at a part corresponding to protruding end 2241bb of third transparent member 2841b, which eliminates the necessity for an additional space to dispose depression sensor 1003A and allows efficient use of the space in electronic device 1001.

In above-described Embodiment 1 to Embodiment 4, the present invention is also applicable to a case where a program for signal processing is recorded or written into a machine readable recording medium such as a memory, disk, tape, CD or DVD to perform the operation of the present invention, and it is possible to achieve the operations and effects similar to those of the respective embodiments.

### INDUSTRIAL APPLICABILITY

The present invention is suitable for use in an electronic device having a touch panel, an input processing method, and a program.

The present invention has an effect of being able to detect which part of a touch panel is pressed not only in a case where the touch panel is touched with a finger but also in a case where the touch panel is touched with a gloved finger or with a nail. In addition, the present invention is applicable to an electronic device using an electrostatic-capacitance touch panel such as a smartphone.

### REFERENCE SIGNS LIST

100 Input apparatus
101, 1002, 1002A Touch panel layer
102, 702 Coordinate acquiring section
103, 1003, 1003A Depression sensor (depression detecting section)
104 Depression acquiring section
105, 402, 703 State determination section
106, 704 Touch coordinate processing section
107 Hover coordinate processing section
108, 408, 708, 1008 Control section
701, 1007 Storage section
1001 Electronic device
1004, 1004A Display section
1110 Housing
1111 Home key
1212 Glass (transparent member)
1370 Finger (conductive indicator)
1530 Icon
1780 Glove
1871 Nail
2241 LCD
2242 Backlight
2841a Second transparent member
2841b Third transparent member

1. An electronic device comprising:
a planar display section;
a planar transparent member that has a predetermined transmittance and that is disposed while being overlapped with the display section;
a touch panel layer that is disposed between the display section and the transparent member while being overlapped with the display section and that detects two-dimensional coordinates of an indicator having predetermined conductivity along a surface of the display section and that detects a vertical distance from the indicator to the touch panel layer; and
a depression detecting section that detects deformation of at least the transparent member, wherein:
when the vertical distance detected by the touch panel layer is equal to or less than a first value, the electronic device performs processing associated with touch input for at least the two-dimensional coordinates detected by the touch panel layer; and
when the vertical distance is greater than the first value but not greater than a second value that is a value greater than the first value, and also when the depression detecting section detects predetermined deformation, the electronic device performs processing associated with touch input for at least the two-dimensional coordinates.

2. The electronic device according to claim 1, wherein, the electronic device continues to perform the processing associated with the touch input for at least the two-dimensional coordinates as long as the vertical distance is greater than the first value but not greater than the second value even when the depression detecting section no longer detects the predetermined deformation for a predetermined time while the electronic device performs the processing associated with the touch input for at least the two-dimensional coordinates because of the detection of the vertical distance greater than the first value but not greater than the second value and the detection of the predetermined deformation by the depression detecting section.

3. The electronic device according to claim 1, wherein, the electronic device continues to perform the processing associated with the touch input for at least the two-dimensional coordinates as long as the vertical distance is greater than the first value but not greater than the second value even when the depression detecting section no longer detects the predetermined deformation while the electronic device performs the processing associated with the touch input for at least the two-dimensional coordinates because of the detection of the vertical distance greater than the first value but not greater than the second value and the detection of the predetermined deformation by the depression detecting section.

4. The electronic device according to claim 1, wherein the first value is 0.

5. The electronic device according to claim 1, further comprising a housing, wherein
at least part of the transparent member is exposed from the housing.

6. The electronic device according to claim 1, wherein the transparent member and the touch panel layer are integrated into one piece.

7. The electronic device according to claim 1, wherein:
the display section is a rectangle; and
the depression detecting section is disposed along at least one side of the rectangle.

8. The electronic device according to claim 7, wherein:
the display section is a rectangle; and
the depression detecting section is disposed along at least one of short sides of the rectangle.

9. The electronic device according to claim 8, further comprising a home key on a predetermined one of the short sides of the rectangle, wherein
the depression detecting section is disposed along the predetermined one of the short sides.

10. The electronic device according to claim 1, wherein the depression detecting section is disposed while at least part of the depression detecting section is overlapped with the touch panel layer.

11. The electronic device according to claim 1, wherein the depression detecting section is disposed on at least the transparent member.

12. The electronic device according to claim 1, wherein the depression detecting section is disposed on at least the touch panel layer.

13. The electronic device according to claim 1, wherein the depression detecting section is disposed on at least the display section.

14. The electronic device according to claim 1, wherein:
the transparent member is referred to as a first transparent member; and
the display section comprises:
a second transparent member having a planar shape; and
a third transparent member disposed while being overlapped with the second transparent member, wherein:
the second transparent member is disposed closer to the touch panel layer than the third transparent member;
the third transparent member includes a protruding part which protrudes outward from the second transparent member at an end of the display section; and
the depression detecting section is disposed on a part of at least one of the transparent member and the touch panel layer, the part corresponding to the protruding part of the third transparent member.

15. The electronic device according to claim 14, wherein the second transparent member and the third transparent member form a liquid crystal or organic electro luminescence display.

16. An input processing method useable for an electronic device that includes:
a planar display section;
a planar transparent member that has a predetermined transmittance and that is disposed while being overlapped with the display section;
a touch panel layer that is disposed between the display section and the transparent member while being overlapped with the display section and that detects two-dimensional coordinates of an indicator having predetermined conductivity along a surface of the display section and that detects a vertical distance from the indicator to the touch panel layer; and
a depression detecting section that detects deformation of at least the transparent member,
the input processing method comprising:
performing processing associated with touch input for at least the two-dimensional coordinates detected by the touch panel layer, when the vertical distance detected by the touch panel layer is equal to or less than a first value; and
performing processing associated with touch input for at least the two-dimensional coordinates, when the vertical distance is greater than the first value but not greater than a second value that is a value greater than the first value, and also when the depression detecting section detects predetermined deformation.

17. An input processing program for causing a computer to execute the processing for an electronic device that includes:
a planar display section;
a planar transparent member that has a predetermined transmittance and that is disposed while being overlapped with the display section;
a touch panel layer that is disposed between the display section and the transparent member while being overlapped with the display section and that detects two-dimensional coordinates of an indicator having predetermined conductivity along a surface of the display section and that detects a vertical distance from the indicator to the touch panel layer; and
a depression detecting section that detects deformation of at least the transparent member,
the input processing program causing the computer to execute the processing comprising:
performing processing associated with touch input for at least the two-dimensional coordinates detected by the touch panel layer, when the vertical distance detected by the touch panel layer is equal to or less than a first value; and
performing processing associated with touch input for at least the two-dimensional coordinates, when the vertical distance is greater than the first value but not greater than a second value that is a value greater than the first value, and also when the depression detecting section detects predetermined deformation.
